(19) United States
(12) Patent Application Publication
(10) Pub. No.: US 2026/0101807 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventors: Yubin SONG, Suwon-si (KR); Pilkyu KANG, Suwon-si (KR); Jaewha PARK, Suwon-si (KR); Eunmi KIM, Suwon-si (KR); Kunsang PARK, Suwon-si (KR)

(73) Assignee: SAMSUNG ELECTRONICS CO., LTD., Suwon-si (KR)

(21) Appl. No.: 19/170,634

(22) Filed: Apr. 4, 2025

(30) Foreign Application Priority Data
Oct. 7, 2024 (KR) 10-2024-0135893

(51) Int. Cl. H01L 23/31; H01L 23/00; H01L 23/48; H01L 25/07

(52) U.S. Cl. CPC H10W 74/121; H10W 20/20; H10W 90/00; H10W 90/792

(57) ABSTRACT

A semiconductor package includes: a semiconductor chip including through-electrodes penetrating through a substrate, and back pads on the through-electrodes; a side passivation layer around the semiconductor chip, and extending along the side surface of the substrate; a gap-fill dielectric layer covering at least a portion of the side passivation layer; a bonding dielectric layer on the gap-fill dielectric layer; and a top semiconductor chip on the semiconductor chip, and including a bonding insulating layer contacting the bonding dielectric layer. The through-electrodes have first upper portions protruding to the back surface of the substrate, the side passivation layer has a second upper portion protruding to the back surface of the substrate and spaced apart from the first upper portions in a horizontal direction. The gap-fill dielectric layer fills a space between the first upper portions and the second upper portion.

### CROSS-REFERENCE TO RELATED APPLICATION

This application claims priority under 35 U.S.C. 119(a) to Korean Patent Application No. 10-2024-0135893, filed on Oct. 7, 2024, in the Korean Intellectual Property Office, the disclosure of which is incorporated by reference herein in its entirety.

### BACKGROUND

The present disclosure concept relates to a semiconductor package.

As electronic products require high performance and miniaturization, demand for semiconductor packages in which different types of semiconductor chips are integrated into a single chip is increasing. Accordingly, a technology is being developed in which semiconductor chips, which are electrically connected through a Through Silicon Via (TSV)are stacked vertically.

### SUMMARY

One or more example embodiments relate to a semiconductor package and to providing a semiconductor package which may have improved reliability.

According to an aspect of an embodiment, a semiconductor package includes: a semiconductor chip including a substrate including a front surface, a back surface opposite to the front surface, and a side surface extending between the front surface and the back surface, front pads disposed on the front surface, through-electrodes electrically connected to the front pads and penetrating through the substrate, and back pads disposed on the through-electrodes; a side passivation layer around the semiconductor chip and extending along the side surface of the substrate; a gap-fill dielectric layer on the back surface of the substrate and covering at least a portion of each of the through-electrodes and the side passivation layer; a bonding dielectric layer on the gap-fill dielectric layer and contacting at least a portion of each of the back pads; and a top semiconductor chip on the semiconductor chip, the top semiconductor chip including connection pads contacting the back pads, and a bonding insulating layer contacting at least a portion of each of the connection pads and contacting the bonding dielectric layer, wherein the through-electrodes have first upper portions protruding to the back surface of the substrate, the side passivation layer includes a second upper portion protruding to the back surface of the substrate and spaced apart from the first upper portions in a horizontal direction, and the gap-fill dielectric layer fills a space between the first upper portions and the second upper portion.

According to an aspect of an embodiment, a semiconductor package includes: a semiconductor chip including a substrate including a front surface and a back surface opposite to the front surface, front pads on the front surface, through-electrodes electrically connected to the front pads and penetrating through the substrate and protruding to the back surface, and back pads on the through-electrodes; a side passivation layer surrounding the semiconductor chip; a dielectric layer covering at least a portion of each of the semiconductor chip and the side passivation layer, and surrounding the through-electrodes and the back pads on the back surface of the substrate; a top semiconductor chip on the dielectric layer, the top semiconductor chip including connection pads electrically connected to the back pads; and bump structures below the semiconductor chip and connected to the front pads, wherein the side passivation layer includes an upper surface and a lower surface opposite to the upper surface, the upper surface of the side passivation layer and the back surface of the substrate extend in a same direction, and a first distance between the back surface of the substrate and a top surface of the dielectric layer is greater than a second distance between the upper surface of the side passivation layer and the top surface of the dielectric layer.

According to an aspect of an embodiment, a semiconductor package includes: a semiconductor chip including a substrate including a front surface and a back surface opposite to the front surface, front pads on the front surface, through-electrodes electrically connected to the front pads and penetrating through the substrate and protruding to the back surface, and back pads disposed on the through-electrodes; a side passivation layer surrounding the semiconductor chip and spaced from the through-electrodes in a horizontal direction; a dielectric layer covering at least a portion of each of the semiconductor chip and the side passivation layer, and surrounding the through-electrodes and the back pads on the back surface of the substrate; and a top semiconductor chip on the semiconductor chip and the dielectric layer, the top semiconductor chip including connection pads contacting the back pads.

### BRIEF DESCRIPTION OF DRAWINGS

The above and other aspects, features, and advantages of the present disclosure will be more apparent from the following detailed description, taken in conjunction with the accompanying drawings, in which:

FIG. 1A is a cross-sectional view of a semiconductor package according to one or more example embodiments;

FIG. 1B is a cross-sectional view taken along line I-I′ of FIG. 1A according to one or more example embodiments;

FIGS. 2A, 2B, 2C, 2D, 2E, 2F, 2G, 2H, 2I, 2J, 2K, 2L and 2M are drawings for illustrating a manufacturing process of a recombinant wafer according to one or more example embodiments;

FIGS. 3A, 3B and 3Care drawings for illustrating the manufacturing process of the semiconductor package of FIG. 1A according to one or more example embodiments;

FIG. 4 is a cross-sectional side view of a semiconductor package according to one or more example embodiments;

FIG. 5 is a cross-sectional side view of a semiconductor package according to one or more example embodiments;

FIGS. 6A, 6B and 6C are drawings for illustrating the manufacturing process of the semiconductor package of FIG. 5 according to one or more example embodiments;

FIG. 7 is a cross-sectional side view of a semiconductor package according to one or more example embodiments; and

FIGS. 8A, 8B, 8C and 8D are drawings for illustrating the manufacturing process of the semiconductor package of FIG. 7 according to one or more example embodiments.

### DETAILED DESCRIPTION

Hereinafter, example embodiments will be described with reference to the accompanying drawings. Unless otherwise specified, in this specification, terms such as “upper,” “upper surface,” “lower,” “lower surface,” “side” and the like, are based on the drawings, and actually, may vary depending on the direction in which the components are disposed.

In addition, ordinal numbers such as “first,” “second,” “third,” or the like, may be used as labels for specific elements, step portions, directions, or the like, to distinguish various elements, step portions, directions, or the like, from each other. Terms that are not described using “first,” “second,” or the like, in the specification may still be referred to as “first” or “second”, or the like, in the claims. Additionally, terms referenced by a specific ordinal number (for example, “first” in a particular claim) may be described elsewhere with a different ordinal number (for example, “second” in the specification or another claim).

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

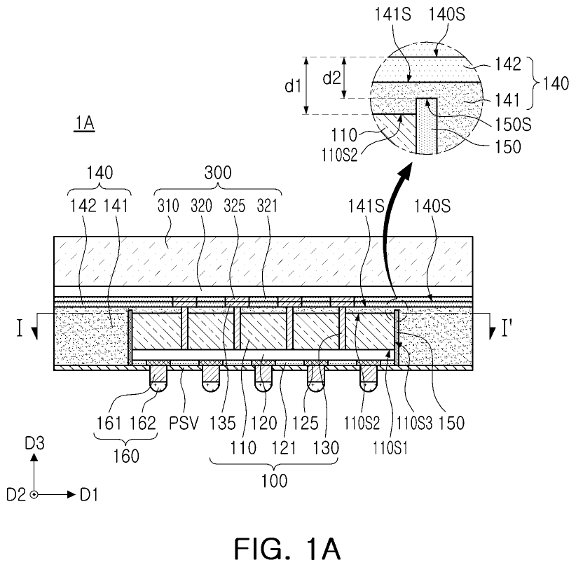

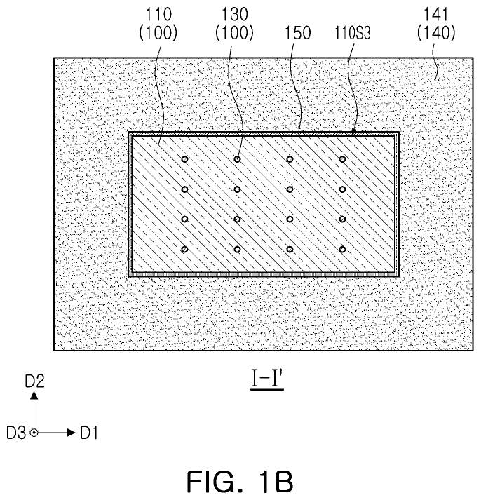

FIG. 1A is a cross-sectional side view of a semiconductor package 1A according to one or more example embodiments, and FIG. 1B is a cross-sectional view taken along line I-I′ of FIG. 1A.

Referring to FIGS. 1A and 1B, a semiconductor package 1A of one or more example embodiments may include a semiconductor chip 100, a dielectric layer 140, and a side passivation layer 150. According to one or more example embodiments, the semiconductor package 1A may further include a top semiconductor chip 300.

The semiconductor chip 100 may be, for example, a logic chip such as a central processor (CPU), a graphics processor (GPU), a field programmable gate array (FPGA), an application processor (AP), a digital signal processor (DSP), a cryptographic processor, a microprocessor, a microcontroller, an analog-to-digital converter, an application-specific IC (ASIC), and the like, and a memory chip including a volatile memory such as a dynamic RAM (DRAM), a static RAM (SRAM), and the like, and/or a non-volatile memory such as a phase change RAM (PRAM), a magnetic RAM (MRAM), a resistive RAM (RRAM), a flash memory device, and the like. The semiconductor chip 100 may be provided as two or more semiconductor chips, which are adjacent to each other in horizontal directions (D1 and D2).

The semiconductor chip 100 may include a substrate 110, a circuit layer 120, a bonding insulating layer 121, front pads 125, through-electrodes 130, and back pads 135. The semiconductor chip 100 may be a semiconductor chip in a bare state in which no separate bumps or interconnections are formed. In one or more example embodiments, the semiconductor chip 100 may be a packaged-type semiconductor chip.

The substrate 110 may have a front surface 110S1 and a back surface 110S2, opposite to each other. The substrate 110 may be a semiconductor wafer including a semiconductor element including, but not limited to, silicon, germanium, or a compound semiconductor such as silicon carbide (SiC), gallium arsenide (GaAs), indium arsenide (InAs), and indium phosphide (InP). The front surface 110S1 of the substrate 110 may be a surface on which an active region doped with impurities is formed (e.g., a surface facing the circuit layer 120), and the back surface 110S2 of the substrate 110 may be a surface on which an active region is not formed.

The circuit layer 120 may be disposed on the front surface 110S1 of the substrate 110. The circuit layer 120 may include an integrated circuit comprised of individual devices formed on the front surface 110S1 of the substrate 110 and an interconnection structure electrically connecting the individual devices to front pads 125. The ‘Individual devices’ may include various active devices and/or passive devices, for example, field effect transistor (FET) devices such as planar FET, FinFET, or the like, memory devices such as flash memory, DRAM, SRAM, Electrically Erasable Programmable Read-Only Memory (EEPROM), PRAM, MRAM, Ferroelectric RAM (FeRAM), RRAM, or the like, logic devices such as AND devices, OR devices, NOT devices, or the like, and system large scale integration (LSI), CMOS image sensors (CIS), and microelectromechanical systems (MEMS). The ‘interconnection structure’ may be formed of a multilayer structure including an interconnection pattern and a via formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof. The circuit layer 120 may further include an interlayer insulating layer covering the ‘individual devices’ and the ‘interconnection structure’. The interlayer insulating layer may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof.

The front pads 125 may be connection terminals electrically connected to the integrated circuit of the circuit layer 120. The front pads 125 may include one of copper (Cu), nickel (Ni), titanium (Ti), aluminum (Al), gold (Au), silver (Ag), or an alloy thereof. The front pads 125 may be connection terminals (e.g., aluminum pads) of a bare chip, but one or more example embodiments are not limited thereto. According to one or more example embodiments, the front pads 125 may be connection structures (e.g., copper pads) formed on the connection terminals of a bare chip. A barrier layer including at least one of titanium (Ti), titanium nitride (TiN), tantalum (Ta), and tantalum nitride (TaN) may be formed between the front pads 125 and the bonding insulating layer 121.

The bonding insulating layer 121 (or referred to as an “insulating layer”) may be formed to be disposed below the circuit layer 120 and may surround the front pads 125. The bonding insulating layer 121 may include, for example, at least one of silicon oxide (SiO), silicon nitride (SiN), and silicon carbon nitride (SiCN).

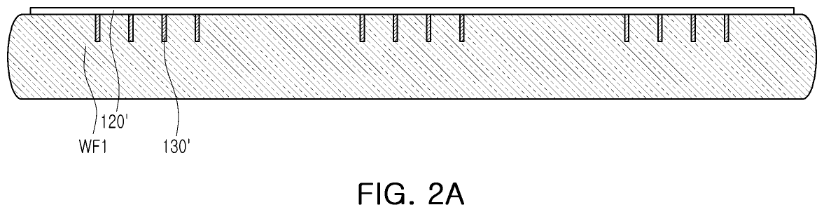

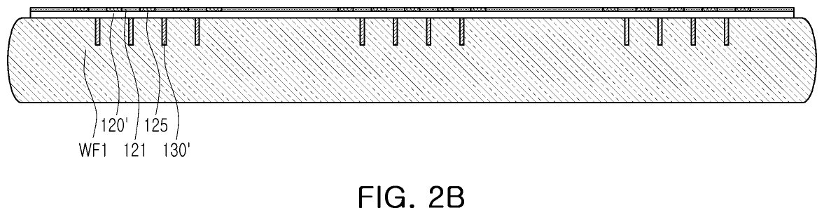

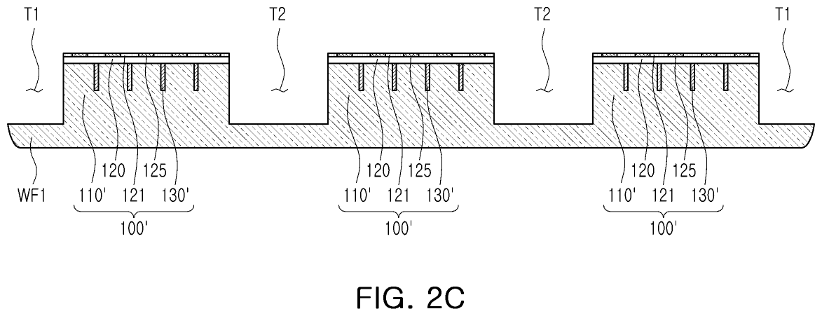

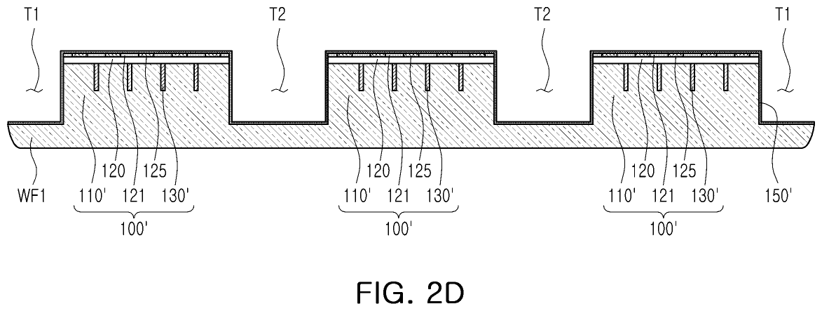

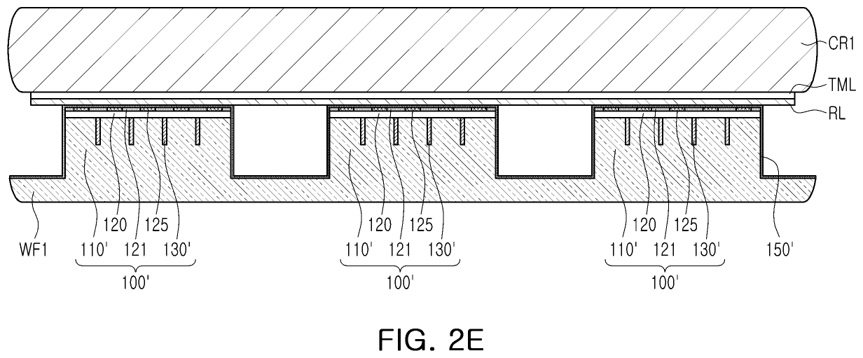

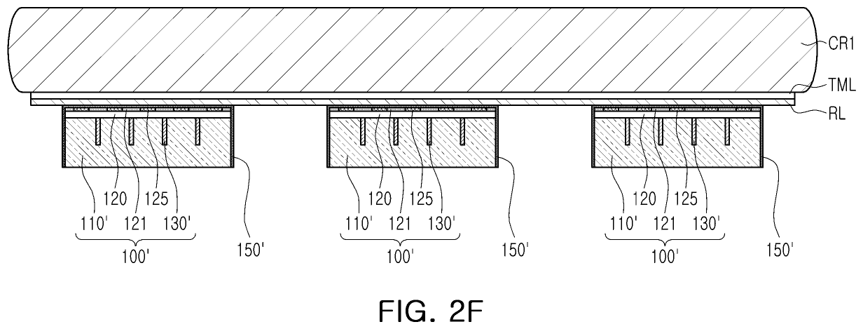

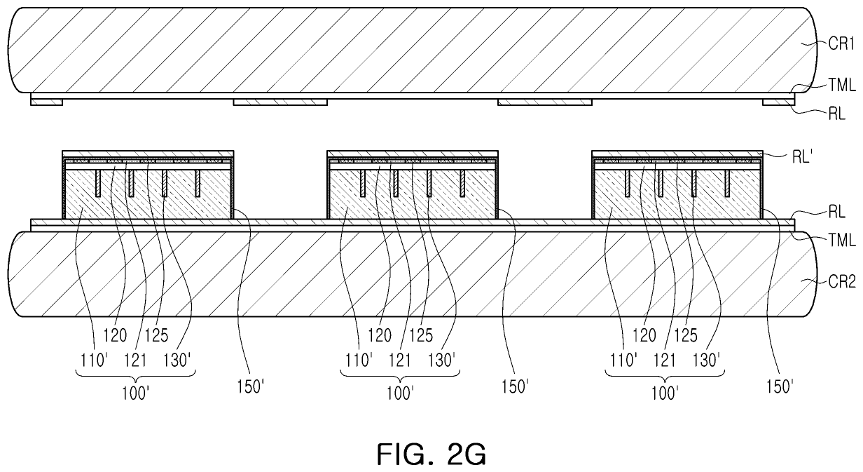

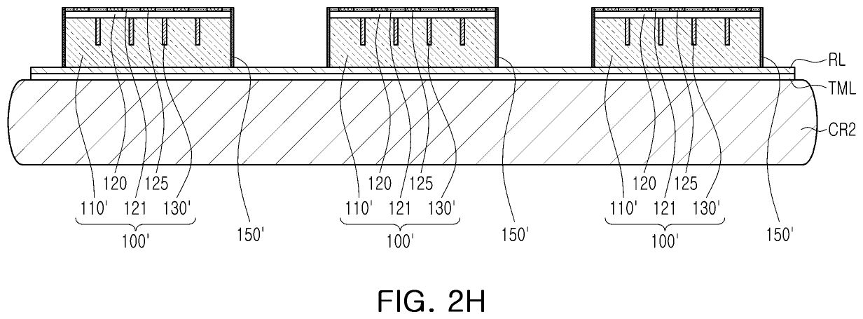

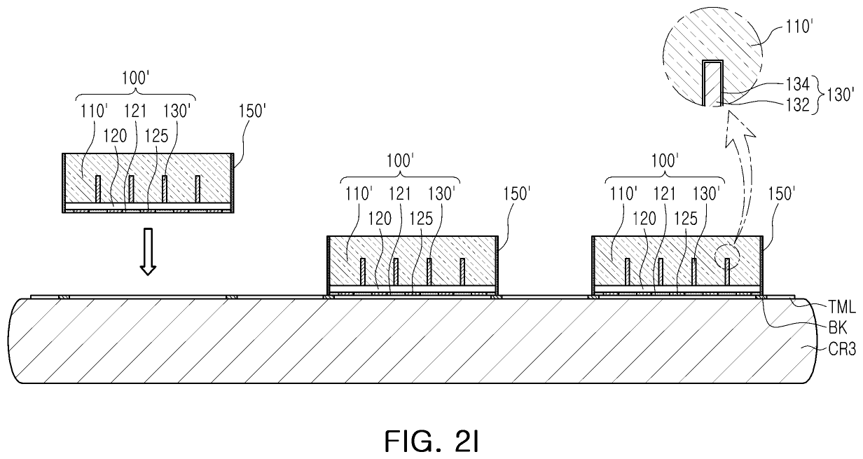

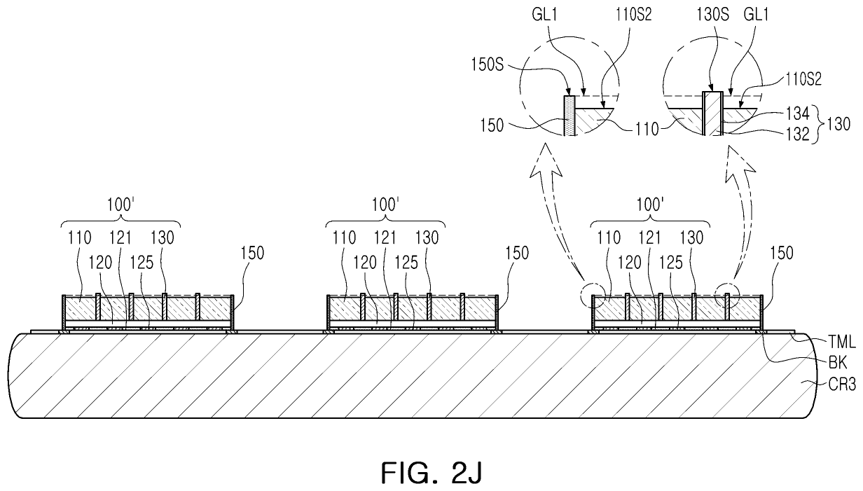

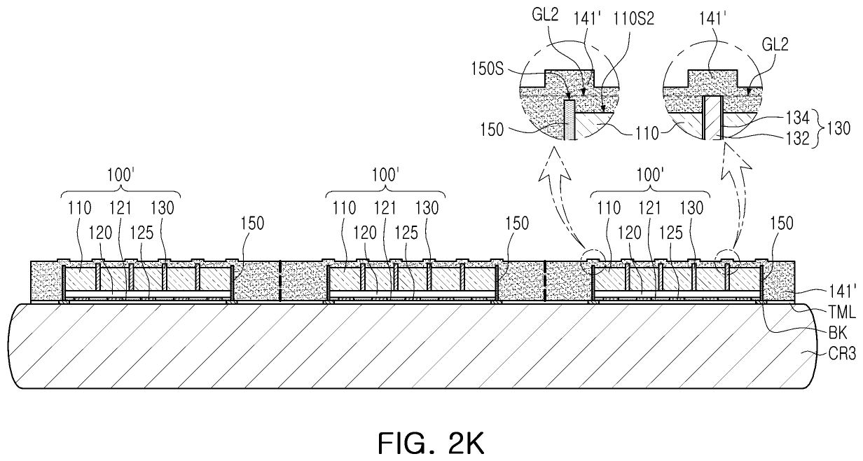

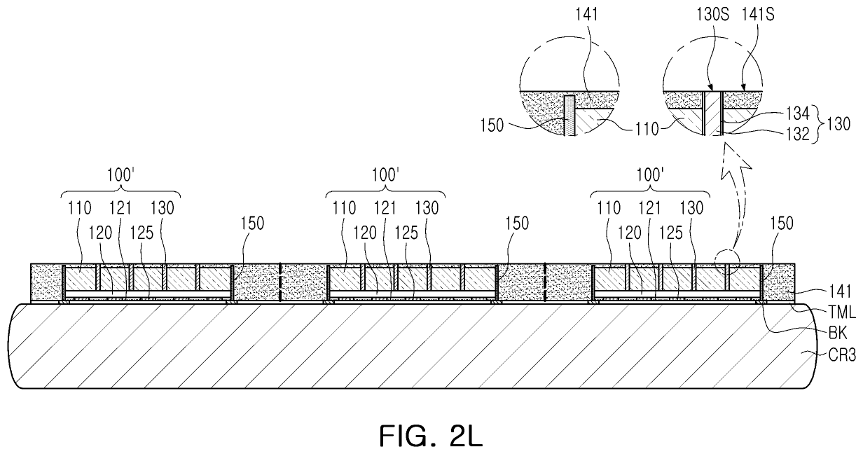

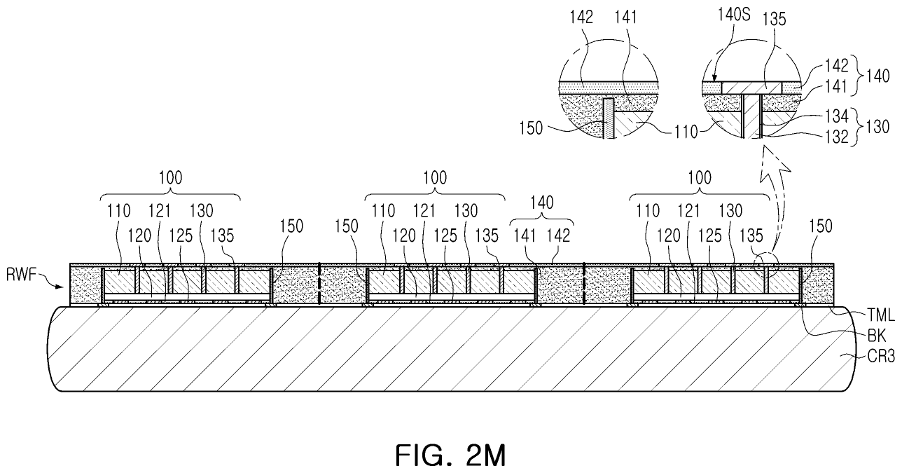

The through-electrodes 130 may electrically connect the front pads 125 and the back pads 135. The through-electrodes 130 may be electrically connected to the front pads 125 and may extend to a back surface 110S2 of the substrate 110. The through-electrodes 130 may penetrate through the substrate 110 to protrude onto the back surface 110S2. Upper surfaces of the through-electrodes 130, in contact with the back pads 135, may be disposed on the same level as, or higher than, the top surface (may also be referred to as an “end”) 150S of the side passivation layer 150 (see FIG. 2K).

The back pads 135 may be respectively disposed on the through-electrodes 130. The back pads 135 may include one of copper (Cu), nickel (Ni), titanium (Ti), aluminum (Al), gold (Au), silver (Ag), or an alloy thereof. The back pads 135 may be spaced apart from the substrate 110. A dielectric layer 140 may be filled between the back pads 135 and the back surface 110S2 of the substrate 110.

Bump structures 160 may be disposed below the semiconductor chip 100. The bump structures 160 may be electrically connected to the front pads 125 of the semiconductor chip 100. The bump structures 160 may connect the semiconductor package 1A to an external device such as a module substrate, a main board, or the like. For example, the bump structures 160 may include a pillar portion 161 and a solder portion 162. The pillar portion 161 may include copper (Cu) or an alloy of copper (Cu), and the solder portion 162 may include a low-melting point metal, for example, tin (Sn) or an alloy including tin (Sn) (e.g., Sn—Ag, or Sn—Ag—Cu). In one or more example embodiments, the bump structures 160 may include only the pillar portion 161 or only the solder portion 162.

The dielectric layer 140 may cover at least a portion of each of the semiconductor chip 100 and the side passivation layer 150, and may surround the side surfaces of the through-electrodes 130 and the side-surfaces of the back pads 135 on the back surface 110S2 of the substrate 110. The dielectric layer 140 may include at least one of silicon oxide (SiO), silicon nitride (SiN), and silicon carbon nitride (SiCN). The dielectric layer 140 may include a gap-fill dielectric layer 141 and a bonding dielectric layer 142. The gap-fill dielectric layer 141 and the bonding dielectric layer 142 may include the same material (e.g., silicon oxide), but one or more example embodiments are not limited thereto.

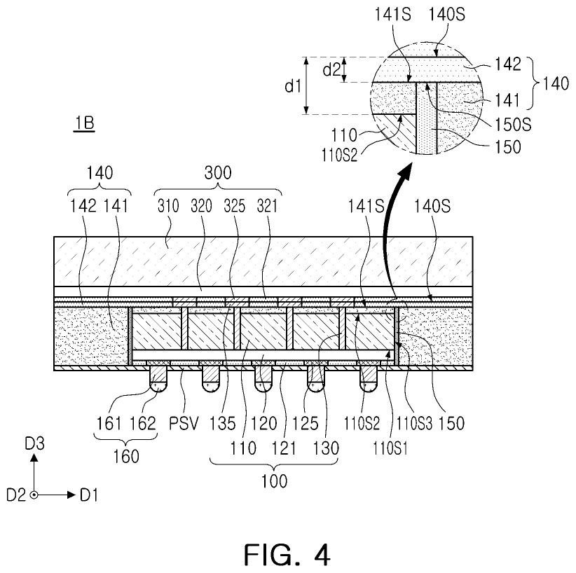

The gap-fill dielectric layer 141 may cover a back surface 110S2 and a side surface of the substrate 110, a portion of a side surface of each of the through-electrodes 130 (meaning a portion thereof protruding to the back surface 110S2), and a side surface and an upper surface (or referred to as a “top surface”) 150S of the side passivation layer 150. According to one or more example embodiments, the top surface 150S of the side passivation layer 150 may be exposed from the gap-fill dielectric layer 141 (the example embodiment of FIG. 4). A lower surface of the gap-fill dielectric layer 141 may be coplanar with a lower surface (or referred to as a “lower surface”) of the side passivation layer 150. The gap-fill dielectric layer 141 may include at least one of silicon oxide (SiO) and silicon nitride (SiN) applied to protect the through-electrodes 130 during a planarization process (e.g., a Chemical Mechanical Planarization (CMP) process).

The bonding dielectric layer 142 may be disposed on an upper surface 141S of the gap-fill dielectric layer 141, and may cover a side surface of each of the back pads 135. The bonding dielectric layer 142 may provide a bonding surface for bonding and coupling the top semiconductor chip 300. The bonding dielectric layer 142 may include a material that can be bonded to, and coupled to, a bonding insulating layer 221 of the top semiconductor chip 300, for example, silicon oxide (SiO) or silicon carbon nitride (SiCN). However, a material forming the dielectric layer 140 is not limited to the example embodiment described above. Depending on the process, a boundary between the bonding dielectric layer 142 and the bonding insulating layer 221 may not be clearly distinguished.

The side passivation layer 150 may be disposed around the semiconductor chip 100. The side passivation layer 150 may extend in a horizontal direction (e.g., in the D1 and D2 directions) along a side surface of the semiconductor chip 100. According to one or more example embodiments, by introducing a side passivation layer 150 surrounding the side surface of the semiconductor chip 100, warpage of the semiconductor chip 100 may be improved, and as a result thereof, the bonding quality between the top semiconductor chip 300 and the semiconductor chip 100 and the reliability of the semiconductor package 1A may be improved.

The side passivation layer 150 may include a material different from the substrate 110. The side passivation layer 150 may include at least one of an oxide and a nitride of a semiconductor material. For example, the side passivation layer 150 may include at least one of silicon oxide (SiO), silicon oxynitride (SiON), silicon nitride (SiN), and silicon carbon nitride (SiCN). In one or more example embodiments, the side passivation layer 150 may serve as a stop line for a leveling process during manufacturing of the recombinant wafer.

The side passivation layer 150 may be spaced apart from the through-electrodes 130 protruding to the back surface 110S2 of the substrate 110 in a horizontal direction. For example, the through-electrodes 130 may have first upper portions protruding to the back surface 110S2 of the substrate 110, and the side passivation layer 150 may have a second upper portion protruding to the back surface 110S2 and spaced apart from the first upper portions of the through-electrodes 130 in a horizontal direction. In one or more example embodiments, the gap-fill dielectric layer 141 may fill a space between the first upper portions of the through-electrodes 130 and the second upper portion of the side passivation layer 150.

Ends of the first upper portions of the through-electrodes 130 may be disposed on the same level as, or higher than, an end 150S of the second upper portions of the side passivation layer 150. The ends of the first upper portions of the through-electrodes 130 may be in contact with the back pads 135, and the end 150S of the second upper portion of the side passivation layer 150 may be spaced apart from the bonding dielectric layer 142. Hereinafter, the “ends” of the second upper portions may be referred to as the “top surface 150S” of the side passivation layer 150.

The top surface 150S of the side passivation layer 150 may be adjacent to a planarized surface provided by an upper surface 141S of the gap-fill dielectric layer 141 and an upper end of each of the through-electrodes 130. A distance between the side passivation layer 150 and the planarized surface may be smaller than a distance between the substrate 110 and the planarized surface. For example, a first distance (d1) between the back surface 110S2 of the substrate 110 and the top surface 140S of the dielectric layer 140 may be larger than a second distance (d2) between the top surface 150S of the side passivation layer 150 and the top surface 140S of the dielectric layer 140.

The side passivation layer 150 may have an upper surface extending in the same direction as the back surface 110S2 of the substrate 110 and a lower surface extending in the same direction as the front surface 110S1 of the substrate 110. The side passivation layer 150 may extend in a single direction between the top surface 150S and the lower surface. For example, the side passivation layer 150 may extend only in a direction intersecting the front surface 110S1 and back surface 110S2 of the semiconductor chip 100.

The top semiconductor chip 300 may be disposed on the semiconductor chip 100. The top semiconductor chip 300 may be a semiconductor chip in a bare state in which no separate bumps or interconnections are formed. In one or more example embodiments, the top semiconductor chip 300 may be a packaged type semiconductor chip. A width of the top semiconductor chip 300 may be equal to or greater than a width of the semiconductor chip 100, but one or more example embodiments are not limited thereto. In one or more example embodiments, the width of the top semiconductor chip 300 may be smaller than the width of the semiconductor chip 100. The top semiconductor chip 300 and the semiconductor chip 100 may be chiplets comprising a Multi-Chip Module (MCM). For example, the top semiconductor chip 300 may include a processor circuit, and the semiconductor chip 100 may include input/output circuits, analog circuits, memory circuits, serial-parallel conversion circuits, or the like.

The top semiconductor chip 300 may include a substrate 310, a circuit layer 320, a bonding insulating layer 321, and connection pads 325. Because the top semiconductor chip 300 may have components substantially the same as, or similar to, the semiconductor chip 100, the same or similar components are indicated by the same or similar reference numerals, and a duplicate description of the same or similar components is omitted. For example, the substrate 310, the circuit layer 320, the bonding insulation layer 321, and the connection pads 325 may have the same or similar characteristics as the substrate 110, the circuit layer 120, the bonding insulation layer 121, and the front pads 125, as described above, respectively.

The bonding insulating layer 321 may be formed to surround the connection pads 325. The bonding insulating layer 321 may provide a bonding surface for coupling to the bonding dielectric layer 142. The bonding insulating layer 321 may include a material that may be bonded to, and coupled to, the bonding dielectric layer 142, for example, silicon oxide (SiO) or silicon carbon nitride (SiCN).

The connection pads 325 may be connection terminals electrically connected to the integrated circuit of the circuit layer 220. The connection pads 325 may be coupled to the back pads 135 of the semiconductor chip 100. The connection pads 325 may include a material that can be bonded to the back pads 135 and coupled thereto, for example, copper (Cu). The connection pads 325 may be a bonding structure formed on a connection terminal (for example, an aluminum pad) of a bare chip.

According to one or more example embodiments, the semiconductor package 1A may further include a passivation layer PSV. The passivation layer PSV may be formed to surround each of the bump structures 160 below the semiconductor chip 100. The passivation layer PSV may protect the front pads 125 and the bump structures 160 from external physical/chemical damage. The passivation layer PSV may include at least one of silicon oxide (SiO) and silicon nitride (SiN), but one or more example embodiments are not limited thereto. The passivation layer PSV may also include a material such as, for example, photosensitive polyimide (PSPI).

FIGS. 2A, 2B, 2C, 2D, 2E, 2F, 2G, 2H, 2I, 2J, 2K, 2L and 2M are drawings for illustrating a manufacturing process of a recombinant wafer RWF according to one or more example embodiments.

Referring to FIG. 2A, a preliminary circuit layer 120′ and preliminary through-electrodes 130′ may be formed on a first semiconductor wafer WF1. The preliminary circuit layer 120′ and the preliminary through-electrodes 130′ may be formed using a photolithography process, an etching process, a plating process, or the like. The preliminary through-electrodes 130′ may be electrically connected to individual devices and interconnection structures within the preliminary circuit layer 120′. The first semiconductor wafer WF1 may be a silicon (Si) wafer to which a back-grinding process for thickness control has not been applied.

Referring to FIG. 2B, front pads 125 and a bonding insulating layer 121 may be formed. The bonding insulating layer 121 may include silicon oxide (SiO) or silicon carbon nitride (SiCN), and may be formed using a chemical vapor deposition (CVD) process. The front pads 125 may be formed within the bonding insulation layer 121 and may be patterned using a photosensitive material layer and a photolithography process. The front pads 125 may include a metal such as copper (Cu), titanium (Ti), or the like, and may be formed by a plating process. The bonding insulation layer 121 and the front pads 125 may be planarized by a CMP process.

Referring to FIG. 2C, first and second trenches T1 and T2 may be formed. The first trench T1 may be formed at an edge of a first semiconductor wafer WF1. The first trench T1 may be formed by partially removing the first semiconductor wafer WF1 and a preliminary circuit layer 120′ by a trim process. The second trench T2 may be formed along a scribe region between preliminary semiconductor chips 100′. The second trench T2 may be formed by partially removing the first semiconductor wafer WF1 and the preliminary circuit layer 120′ by a plasma etching process. The preliminary semiconductor chips 100′ separated by the second trench T2 may include a circuit layer 120, preliminary through-electrodes 130′, front pads 125, and a bonding insulating layer 121.

Referring to FIG. 2D, a preliminary passivation layer 150′ may be formed. The preliminary passivation layer 150′ may be conformally formed along surfaces of the preliminary semiconductor chips 100′ and inner surfaces of the first and second trenches T1 and T2. The preliminary passivation layer 150′ may include, for example, at least one of silicon oxide (SiO), silicon oxynitride (SiON), silicon nitride (SiN), and silicon carbon nitride (SiCN), and may be formed using a CVD process. The preliminary passivation layer 150′ may prevent warpage and damage of the preliminary semiconductor chips 100′ occurring during a subsequent process (e.g., backgrinding process, cleaning process, or the like). The preliminary passivation layer 150′ may be formed to a thickness of about several μm to about several tens of μm, but one or more example embodiments are not limited thereto. The thickness of the preliminary passivation layer 150′ may be determined by comprehensively considering a thermal expansion coefficient of the materials comprising the preliminary semiconductor chips 100′, conditions of the subsequent process, or the like.

Referring to FIG. 2E, a first carrier wafer CR1 may be bonded on the preliminary semiconductor chips 100′. The first carrier wafer CR1 may support the first semiconductor wafer WF1 for subsequent processes. The first carrier wafer CR1 may be a glass wafer having a size corresponding to the first semiconductor wafer WF1. A temporary bonding layer TML and a release layer RL may be formed on one surface of the first carrier wafer CR1. The temporary bonding layer TML may include silicon oxide (SiO). The temporary bonding layer TML may be formed using a deposition process (e.g., a CVD process). The release layer RL may include a material for bonding and debonding the first carrier wafer CR1. For example, the release layer RL may include a metal oxide and may be debonded from the temporary bonding layer TML using an ultraviolet laser, or the like.

Referring to FIG. 2F, preliminary semiconductor chips 100′ may be separated from each other. The preliminary semiconductor chips 100′ may include preliminary substrates 110′ which are separated from each other. The preliminary substrates 110′ may be formed by partially removing the first semiconductor wafer WF1 by a backgrinding process. The preliminary substrate 151′ may be, for example, a semiconductor substrate including silicon (Si). In addition, the preliminary passivation layer 150′ may be separated by the backgrinding process to surround a side surface of each of the preliminary semiconductor chips 100′. The preliminary passivation layer 150′ may suppress warpage occurring when the preliminary semiconductor chips 100′ are individually separated.

Referring to FIG. 2G, a second carrier wafer CR2 may be bonded. The second carrier wafer CR2 may support preliminary semiconductor chips 100′ for subsequent processes. The second carrier wafer CR2 may be a glass wafer having a size corresponding to the first carrier wafer CR1. A temporary bonding layer TML and a release layer RL may be formed on one surface of the second carrier wafer CR2. Next, the first carrier wafer CR1 may be debonded. The first carrier wafer CR1 may be separated, for example, by irradiating the release layer RL with an ultraviolet laser. At least a portion of the release layer RL (hereinafter, referred to as a “residual portion RL” may remain on the preliminary semiconductor chips 100′. Thereafter, the residual portion RL′ of the release layer RL may be removed using a wet cleaning process.

Referring to FIG. 2H, a portion of a preliminary passivation layer 150′ covering upper surfaces of the preliminary semiconductor chips 100′ may be removed. The preliminary passivation layer 150′ may be partially removed by a CMP process. Front pads 125 and a bonding insulation layer 121 of the preliminary semiconductor chips 100′ may be exposed from the preliminary passivation layer 150′. The front pads 125, the bonding insulation layer 121, and the preliminary passivation layer 150′ may share a planarized surface formed by the CMP process. In one or more example embodiments, a portion of the preliminary passivation layer 150′ covering the upper surfaces of the preliminary semiconductor chips 100′ may be removed prior to bonding the first carrier wafer CR1 (see FIG. 2E).

Referring to FIG. 2I, preliminary semiconductor chips 100′ may be bonded on a temporary bonding layer TML of a recombinant carrier CR3. The preliminary semiconductor chips 100′ may be Known Good Dies (KGDs) that have tests completed. The preliminary semiconductor chips 100′ may be attached to a position determined by using a bonding key BK as an alignment key. The preliminary semiconductor chips 100′ may be attached to a temporary bonding layer TML by a hybrid bonding process. The hybrid bonding process may be performed at room temperature and in a thermal atmosphere ranging from about 100° C. to about 300° C. The hybrid bonding process may form a dielectric-dielectric bond and/or a metal-metal bond at room temperature and may perform a heat treatment in a thermal atmosphere ranging from about 100° C. to about 300° C. However, the temperature in the thermal atmosphere is not limited to the above-described range and may vary. A boundary between the bonding insulation layer 121 and the temporary bonding layer TML may not be clearly distinguished. In one or more example embodiments, the side passivation layer 150 may reduce warpage of the preliminary semiconductor chips 100′, thereby improving alignment accuracy of the preliminary semiconductor chips 100′ and the quality of a bonding surface of the preliminary semiconductor chips 100′ provided for hybrid bonding.

The preliminary through-electrodes 130′ may include a via plug 132 and a side barrier film 134. The via plug 132 may extend vertically within the preliminary substrate 110′. The via plug 132 may include, for example, tungsten (W), titanium (Ti), aluminum (Al), or copper (Cu), and may be formed by a plating process, a physical vapor deposition (PVD) process, or a CVD process. The side barrier film 134 may extend along a surface of the via plug 132. The side barrier film 134 may include, for example, titanium (Ti), titanium nitride (TiN), tantalum (Ta), or tantalum nitride (TaN), and may be formed by a plating process, a PVD process, or a CVD process. According to one or more example embodiments, the preliminary through-electrodes 130′ may further include a side insulating film. The side insulating film may be disposed between the side barrier film 134 and the preliminary substrate 110′. The side insulating film may include an insulating material such as silicon oxide, silicon nitride, silicon oxynitride, or the like (for example, High Aspect Ratio Process (HARP) oxide).

Referring to FIG. 2J, through-electrodes 130 may protrude to a back surface 110S2 of the substrate 110. The substrate 110 may be formed by removing an upper portion of the preliminary substrate 110′. For example, a preliminary substrate 110′ may be ground to a first level GL1 using a grinding process, and then the back surface 110S2 of the substrate 110 may be formed so that the through-electrodes 130 protrude using an etch-back process. The first level GL1 may be understood as a reference line contacting a top surface 150S of the side passivation layer 150. The through-electrodes 130 may be formed by removing the preliminary through-electrodes 130′ by a grinding process. The preliminary through-electrodes 130′ may include a material having a higher resistance to the grinding process than the preliminary substrate 110′. Accordingly, upper surfaces 130S of the through-electrodes 130 may be disposed on the same level as, or higher than, the first level GL1.

The side passivation layer 150 may be formed by partially removing the preliminary passivation layer 150′ through a grinding process. The side passivation layer 150 may cover side surfaces of the preliminary semiconductor chips 100′, thereby preventing damage to the preliminary semiconductor chips 100′ during a subsequent cleaning process after formation of the substrate 110. For example, the side passivation layer 150 may prevent a metal material (e.g., a guard ring, an alignment key, or the like) exposed to a side surface of the circuit layer 120 from being exposed to a cleaning solution.

Referring to FIG. 2K, a gap-fill material layer 141′ may be formed. The gap-fill material layer 141′ may be formed to cover the side passivation layer 150 and the preliminary semiconductor chip 100′. The gap-fill material layer 141′ may conformally extend along surfaces of the side passivation layer 150 and the through-electrodes 130. The gap-fill material layer 141′ may include, for example, silicon oxide (SiO), and may be formed using a CVD process. In a subsequent process, a planarized surface may be formed in which the gap-fill material layer 141′ and the through-electrodes 130 are removed to a second level GL2. The second level GL2 may be disposed on a higher level than a top surface 150S of the side passivation layer 150. In one or more example embodiments, the second level GL2 may be disposed on the same level as the top surface 150S of the side passivation layer 150 (see the example embodiment of FIG. 4).

Referring to FIG. 2L, a gap-fill dielectric layer 141 may be formed. The gap-fill dielectric layer 141 may be formed by applying a CMP process to the gap-fill material layer 141′. The gap-fill material layer 141′ may be polished so that upper surfaces 130S of the through-electrodes 130 are exposed. The upper surface 141S of the gap-fill dielectric layer 141 can be coplanar with the upper surfaces 130S of the through-electrodes 130. The gap-fill dielectric layer 141 may surround the side surface of each of the through-electrodes 130 protruding toward the back surface 110S2 of the substrate 110.

Referring to FIG. 2M, back pads 135 and a bonding dielectric layer 142 may be formed. The bonding dielectric layer 142 may include silicon oxide (SiO), and may be formed using a CVD process. The back pads 135 may be formed within a bonding dielectric layer 142 patterned using a photosensitive material layer and a photolithography process. The back pads 135 may include a metal such as copper (Cu), titanium (Ti), or the like, and may be formed by a plating process. The bonding dielectric layer 142 and the back pads 135 may be planarized by a CMP process. According to one or more example embodiments, warpage of the semiconductor chip 100 may be minimized by the side passivation layer 150, and as a result thereof, a recombinant wafer RWF with an improved bonding surface quality may be formed. An upper surface of the bonding dielectric layer 142, i.e., a top surface 140S of the dielectric layer 140, may provide a planarized surface for wafer-to-wafer bonding as described below.

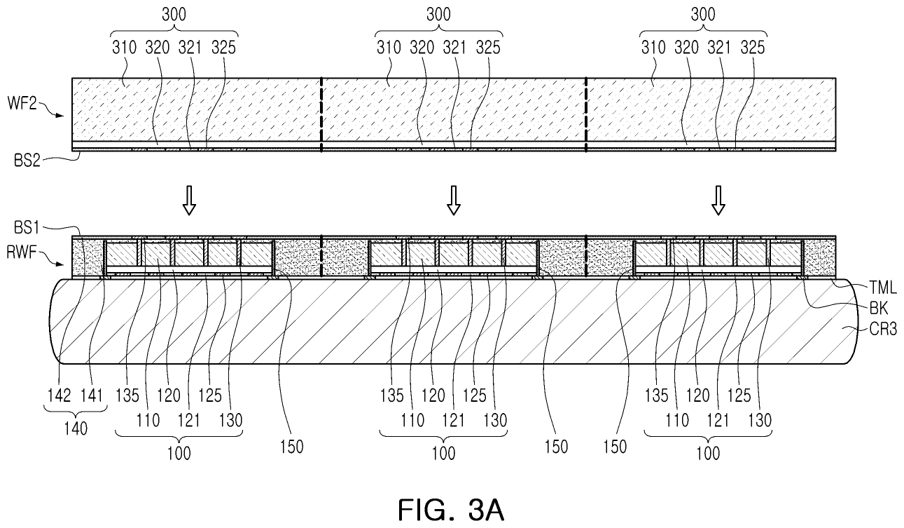

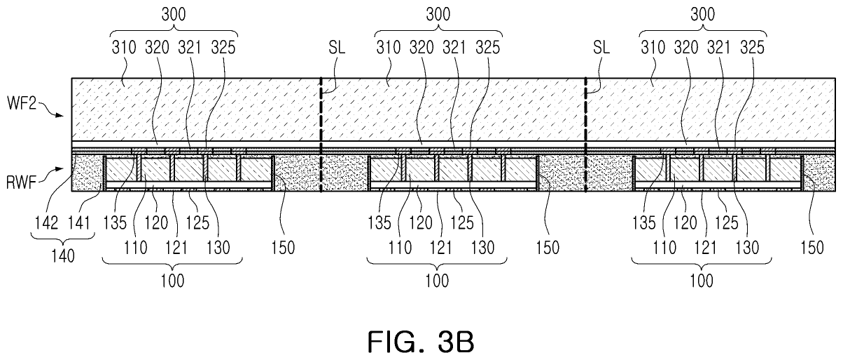

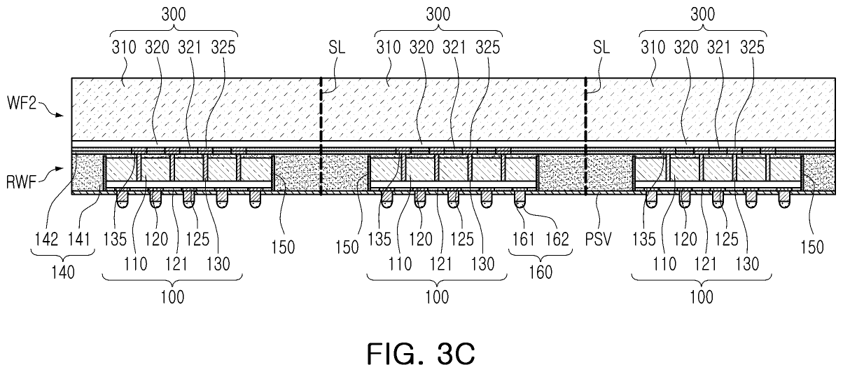

FIGS. 3A, 3B and 3C are drawings for illustrating the manufacturing process of the semiconductor package 1A of FIG. 1A.

Referring to FIG. 3A, a second semiconductor wafer WF2 may be attached onto a recombinant wafer RWF. The second semiconductor wafer WF2 may be a silicon wafer on which an integrated circuit for top semiconductor chips 300 is formed. The second semiconductor wafer WF2 may include a substrate 310, a circuit layer 320, connection pads 325, and a bonding insulating layer 321. The second semiconductor wafer WF2 may be attached thereto in a state in which a thickness of the substrate 310 is adjusted by a backgrinding process, or may be attached to a recombinant wafer RWF and then subjected to a backgrinding process. The recombinant wafer RWF may include a first bonding surface BS1 provided by back pads 135 and a bonding dielectric layer 142. The second semiconductor wafer WF2 may include a second bonding surface BS2 provided by connection pads 325 and a bonding insulating layer 321. The bonding insulating layer 321 of the second semiconductor wafer WF2 and the bonding dielectric layer 142 of the recombinant wafer RWF may form a dielectric-dielectric bond by a hybrid bonding process. In addition, the connection pads 325 of the second semiconductor wafer WF2 and the back pads 135 of the recombinant wafer RWF may form a metal-metal bond by a hybrid bonding process.

Referring to FIG. 3B, a recombinant carrier CR3 and a temporary bonding layer TML may be removed. The recombinant carrier CR3 and the temporary bonding layer TML may be removed by combining a grinding process and an etching process. The temporary bonding layer TML may be completely removed so that the front pads 125 and the side passivation layer 150 of the semiconductor chip 100 are exposed.

Referring to FIG. 3C, a passivation layer PSV and bump structures 160 may be formed. The passivation layer PSV may be formed using a deposition process or a coating process. The passivation layer PSV may be formed to cover lower surfaces of the front pads 125 and a lower surface of the side passivation layer 150. The bump structures 160 may penetrate the passivation layer PSV and may be electrically connected to the front pads 125. Thereafter, semiconductor packages may be separated along a scribe lane SL. According to one or more example embodiments, the quality of a bonding interface between the recombinant wafer RWF and the second semiconductor wafer WF2 is improved, thereby manufacturing a semiconductor package having improved reliability and yield.

FIG. 4 is a cross-sectional side view of a semiconductor package 1B according to one or more example embodiments.

Referring to FIG. 4, the semiconductor package 1B of one or more example embodiments may have the same or similar features as described with reference to FIGS. 1A, 1B, 2A, 2B, 2C, 2D, 2E, 2F, 2G, 2H, 2I, 2J, 2K, 2L, 2M, 3A, 3B and 3C, except that a side passivation layer 150 is in contact with a bonding dielectric layer 142. A top surface 150S of the side passivation layer 150 may be in contact with at least a portion of the bonding dielectric layer 142. Upper ends of through-electrodes 130, an upper surface 141S of a gap-fill dielectric layer 141, and the top surface 150S of the side passivation layer 150 may be substantially coplanar. A structure of one or more example embodiments may be performed by performing a polishing process of the gap-fill dielectric layer 141 described above with reference to FIGS. 2K to 2L until an upper portion of the side passivation layer 150 is exposed.

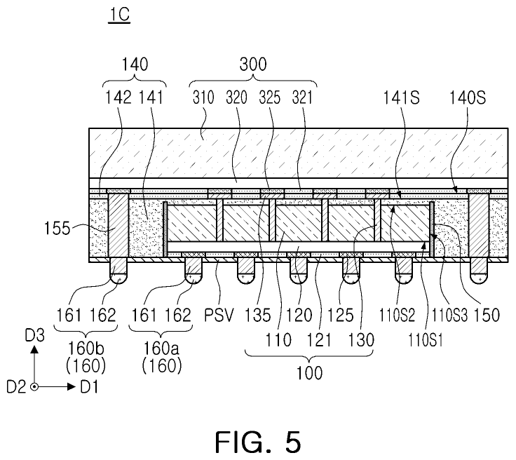

FIG. 5 is a cross-sectional side view of a semiconductor package 1C according to one or more example embodiments.

Referring to FIG. 5, the semiconductor package 1C of one or more example embodiments may have the same or similar features as described with reference to FIGS. 1A, 1B, 2A, 2B, 2C, 2D, 2E, 2F, 2G, 2H, 2I, 2J, 2K, 2L, 2M, 3A, 3B, 3C and 4, except that the semiconductor package 1C further includes conductive posts 155. The conductive posts 155 may electrically connect a top semiconductor chip 300 to bump structures 160. The conductive posts 155 may include, for example, one of copper (Cu), nickel (Ni), titanium (Ti), aluminum (Al), gold (Au), silver (Ag), or an alloy thereof. For example, the bump structures 160 may include first bump structures 160a connected to the front pads 125, and second bump structures 160b connected to the conductive posts 155. The first bump structures 160a may be disposed in a region overlapping the semiconductor chip 100 in a vertical direction D3, for example, a fan-in region. The second bump structures 160b may be disposed in a region not overlapping the semiconductor chip 100 in a vertical direction D3, for example, a fan-out region. The conductive posts 155 may penetrate the gap-fill dielectric layer 141 and the bonding dielectric layer 142, and may connect the connection pads 325 of the top semiconductor chip 300 and the second bump structures 160b.

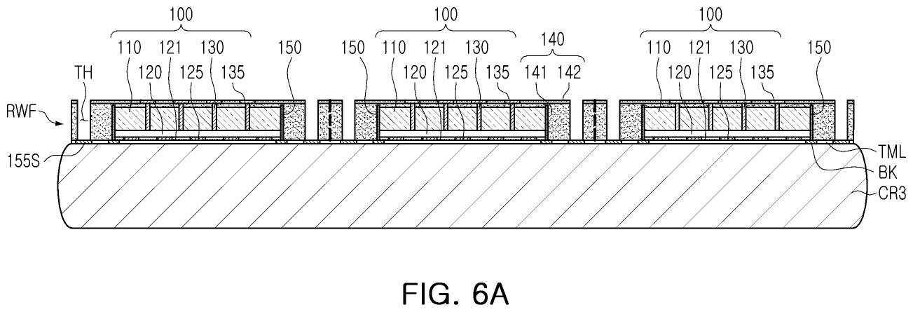

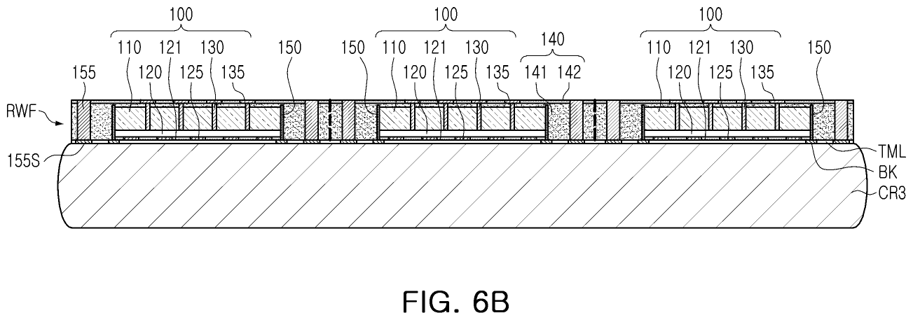

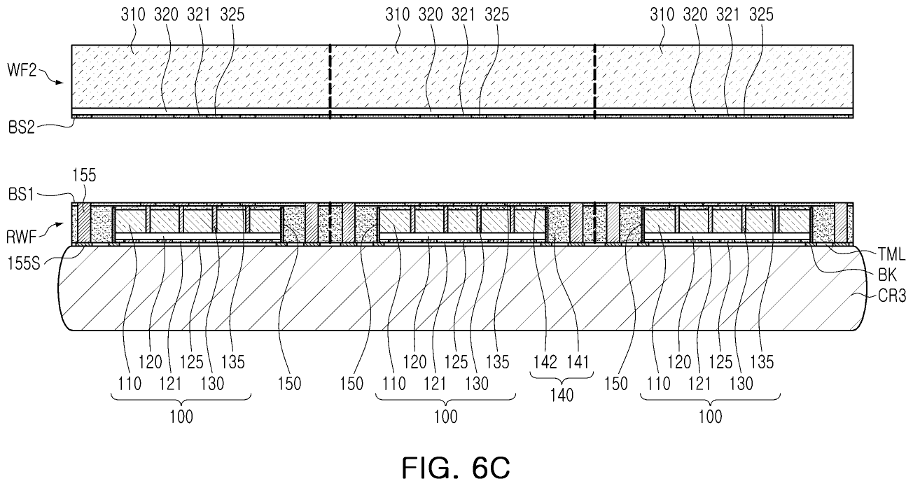

FIGS. 6A, 6B and 6C are drawings for illustrating the manufacturing process of the semiconductor package 1C of FIG. 5.

Referring to FIG. 6A, through-holes TH penetrating through a recombinant wafer RWF may be formed. The through-holes TH may be formed by partially etching the dielectric layer 140. The through-holes TH may be formed to expose at least a portion of a plating seed layer 155S. The recombinant wafer RWF may be formed through the manufacturing process of FIGS. 2A, 2B, 2C, 2D, 2E, 2F, 2G, 2H, 2I, 2J, 2K, 2L and 2M.

Referring to FIG. 6B, conductive posts 155 may be formed. The conductive posts 155 may be formed by performing an electroplating process using the plating seed layer 155S. The conductive posts 155 may include copper (Cu). The conductive posts 155 may have a cylindrical shape, but one or more example embodiments are not limited thereto. The conductive posts 155 may be planarized to form a bonding surface together with the bonding dielectric layer 142 and the back pads 135.

Referring to FIG. 6C, a second semiconductor wafer WF2 may be attached. The second semiconductor wafer WF2 may be a wafer on which an integrated circuit for top semiconductor chips 300 is formed. The recombinant wafer RWF may include a first bonding surface BS1 provided by conductive posts 155, back pads 135, and a bonding dielectric layer 142. The second semiconductor wafer WF2 may include a second bonding surface BS2 provided by connection pads 325 and a bonding insulating layer 321. The connection pads 325 of the second semiconductor wafer WF2 and the back pads 135 and conductive posts 155 of the recombinant wafer RWF may form a metal-metal bond by a hybrid bonding process.

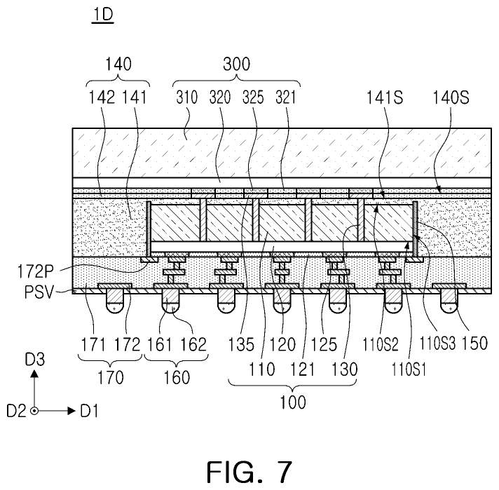

FIG. 7 is a cross-sectional side view of a semiconductor package 1D according to one or more example embodiments.

Referring to FIG. 7, the semiconductor package 1D of one or more example embodiments may have the same or similar features as described with reference to FIGS. 1A, 1B, 2A, 2B, 2C, 2D, 2E, 2F, 2G, 2H, 2I, 2J, 2K, 2L, 2M, 3A, 3B, 3C, 4, 5, 6A, 6B and 6C, except that the semiconductor package 1D further includes a redistribution structure 170. The redistribution structure 170 may be disposed between the semiconductor chip 100 and the bump structures 160. The redistribution structure 170 may electrically connect the front pads 125 of the semiconductor chip 100 and the bump structures 160. Because the front pads 125 are redistributed by the redistribution structure 170, a layout of the bump structures 160 may be variously designed. In one or more example embodiments, the side passivation layer 150 has an upper portion adjacent to a back surface 110S2 of the substrate 110 and a lower portion adjacent to a front surface 110S1 of the substrate 110, and can extend in a single direction between the upper portion and the lower portion.

The redistribution structure 170 may include an insulating material layer 171 and redistribution patterns 172. The insulating material layer 171 may be disposed between the semiconductor chip 100 and the bump structures 160. The insulating material layer 171 may include silicon oxide, or the like. The insulating material layer 171 may be stacked in a plurality of layers according to the number of layers of the redistribution patterns 172. A boundary between the insulating material layers 171 may not be clearly distinguished.

The redistribution patterns 172 may electrically connect the front pads 125 and the conductive posts 155 to the bump structures 160. The redistribution patterns 172 may be disposed within the insulating material layer 171, and may connect the front pads 125 and the bump structures 160. The redistribution patterns 172 can include, for example, copper (Cu), aluminum (Al), silver (Ag), tin (Sn), gold (Au), nickel (Ni), lead (Pb), titanium (Ti), or an alloy thereof. The redistribution patterns 172 may include a ground pattern, a power pattern, and a signal pattern. The signal pattern may provide a transmission path for a data signal transmitted from the semiconductor chip 100 and the top semiconductor chip 300, and a data signal transmitted from the outside. In one or more example embodiments, the redistribution patterns 172 may include key patterns 172P used as an alignment key of the semiconductor chip 100. The redistribution patterns 172 may be formed in more or less layers than those shown in the drawing (three layers). The redistribution patterns 172 may be connected by redistribution vias in a vertical direction D3.

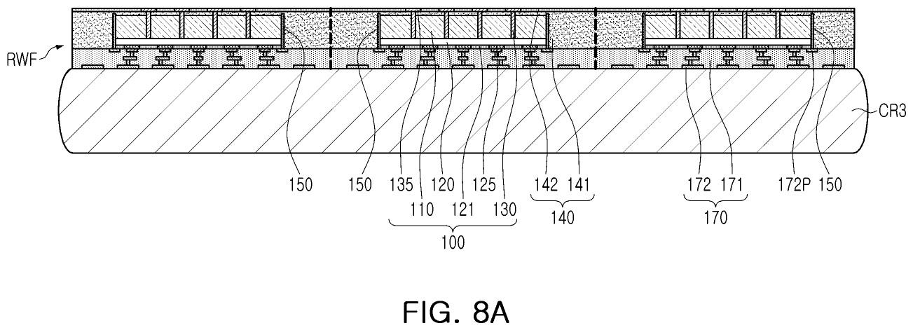

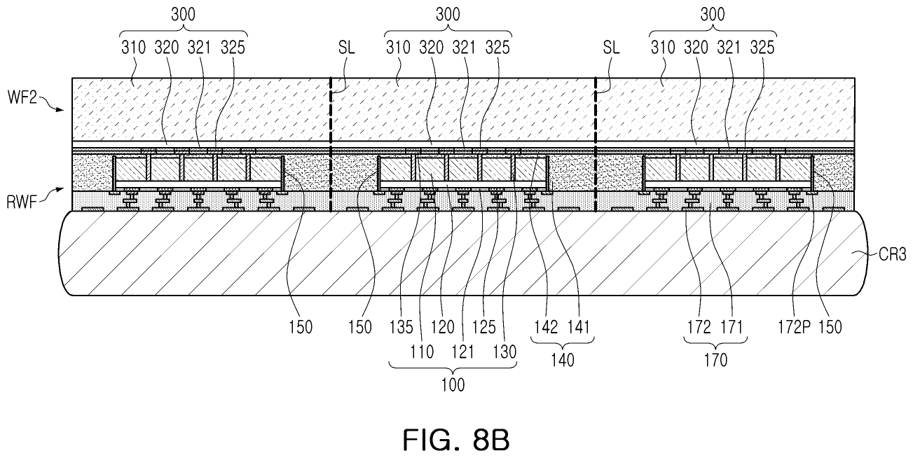

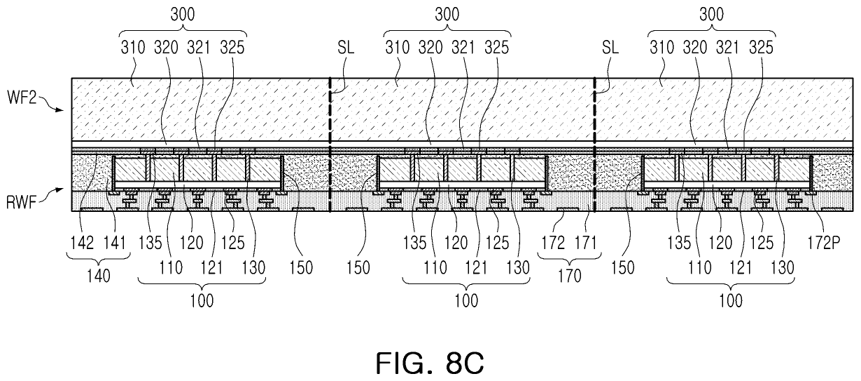

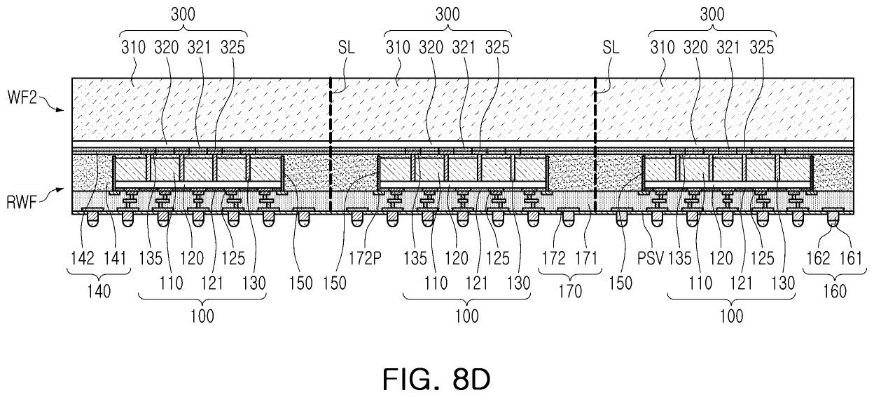

FIGS. 8A, 8B, 8C and 8D are drawings for illustrating the manufacturing process of the semiconductor package (ID) of FIG. 7, according to one or more example embodiments.

Referring to FIG. 8A, a redistribution structure 170 and a recombinant wafer RWF may be formed on a recombinant carrier CR3. The redistribution structure 170 may include an insulating material layer 171 and redistribution patterns 172. The insulating material layer 171 may be formed using a deposition process (e.g., a CVD process). The insulating material layer 171 may form a dielectric-dielectric bond with the bonding insulating layer 121 of the recombinant wafer RWF. A key pattern 172P of the redistribution structure 170 may be used as an alignment key to determine an attachment position of the semiconductor chip 100. The recombinant wafer RWF of one or more example embodiments may be formed through a manufacturing process similar to that referred to in FIGS. 2I, 2J, 2K, 2L and 2M, except that the redistribution structure 170 may be formed on the recombinant carrier CR3.

Referring to FIG. 8B, a second semiconductor wafer WF2 may be attached. The second semiconductor wafer WF2 may be a wafer on which an integrated circuit for top semiconductor chips 300 is formed. The recombinant wafer RWF may include a bonding surface provided by back pads 135 and a bonding dielectric layer 142. The second semiconductor wafer WF2 may include a bonding surface provided by connection pads 325 and a bonding insulating layer 321. The connection pads 325 of the second semiconductor wafer WF2 and the back pads 135 of the recombinant wafer RWF may form a metal-metal bond by a hybrid bonding process.

Referring to FIG. 8C, a recombinant carrier CR3 may be removed. The recombinant carrier CR3 may be removed by combining a grinding process and an etching process. The recombinant carrier CR3 may be removed so that redistribution patterns 172 of the redistribution structure 170 are exposed.

Referring to FIG. 8D, a passivation layer PSV and bump structures 160 may be formed below the redistribution structure 170. The passivation layer PSV may be formed using a deposition process or a coating process. The passivation layer PSV may be formed to cover the redistribution patterns 172. The bump structures 160 may penetrate the passivation layer PSV and may be electrically connected to the redistribution patterns 172. Thereafter, the semiconductor packages may be separated along a scribe lane SL.

As set forth above, according to one or more example embodiments, a semiconductor package having improved reliability may be provided by introducing a side passivation layer surrounding a semiconductor chip.

The various and beneficial advantages and effects of one or more example embodiments are not limited to the above-described content, and may be more apparent through description of one or more example embodiments.

While one or more example embodiments have been particularly illustrated and described above, it will be apparent to those skilled in the art that modifications and variations could be made therein without departing from the spirit and scope of the following claims.

What is claimed is:

1. A semiconductor package comprising:
a semiconductor chip comprising:
a substrate comprising a front surface, a back surface opposite to the front surface, and a side surface extending between the front surface and the back surface;
front pads disposed on the front surface;
through-electrodes electrically connected to the front pads and penetrating through the substrate; and
back pads disposed on the through-electrodes;
a side passivation layer around the semiconductor chip and extending along the side surface of the substrate;
a gap-fill dielectric layer on the back surface of the substrate and covering at least a portion of each of the through-electrodes and the side passivation layer;
a bonding dielectric layer on the gap-fill dielectric layer and contacting at least a portion of each of the back pads; and
a top semiconductor chip on the semiconductor chip, the top semiconductor chip comprising:
connection pads contacting the back pads; and
a bonding insulating layer contacting at least a portion of each of the connection pads and contacting the bonding dielectric layer,
wherein the through-electrodes have first upper portions protruding to the back surface of the substrate,
wherein the side passivation layer comprises a second upper portion protruding to the back surface of the substrate and spaced apart from the first upper portions in a horizontal direction, and
wherein the gap-fill dielectric layer fills a space between the first upper portions and the second upper portion.

2. The semiconductor package of claim 1, wherein the substrate of the semiconductor chip comprises a first material, and
wherein the side passivation layer comprises a second material, different from the first material.

3. The semiconductor package of claim 2, wherein the first material comprises silicon (Si) or a silicon compound, and
wherein the second material comprises at least one of silicon oxide (SiO), silicon oxynitride (SiON), silicon nitride (SiN), and silicon carbonitride (SiCN).

4. The semiconductor package of claim 1, wherein the gap-fill dielectric layer comprises at least one of silicon oxide (SiO) and silicon nitride (SiN).

5. The semiconductor package of claim 1, wherein ends of the first upper portions of the through-electrodes are on a same level as, or higher than, an uppermost end of the second upper portion of the side passivation layer.

6. The semiconductor package of claim 5, wherein the ends of the first upper portions contact the back pads.

7. The semiconductor package of claim 5, wherein the uppermost end of the second upper portion of the side passivation layer contacts the bonding dielectric layer.

8. The semiconductor package of claim 1, wherein the side passivation layer comprises a lower portion, opposite to the second upper portion, and
wherein the side passivation layer extends between the second upper portion and the lower portion.

9. The semiconductor package of claim 1, wherein each of the bonding dielectric layer and the bonding insulating layer comprises at least one of silicon oxide (SiO) and silicon carbon nitride (SiCN).

10. The semiconductor package of claim 1, further comprising:
first bump structures disposed in a region overlapping the semiconductor chip, and connected to the front pads; and
second bump structures disposed on opposite sides of the first bump structures.

11. The semiconductor package of claim 10, further comprising:
conductive posts penetrating through the gap-fill dielectric layer and the bonding dielectric layer, and connecting the connection pads of the top semiconductor chip and the second bump structures.

12. The semiconductor package of claim 1, further comprising:
bump structures below the semiconductor chip and the gap-fill dielectric layer; and
a redistribution structure electrically connecting the front pads and the bump structures.

13. The semiconductor package of claim 12, wherein the redistribution structure comprises:
an insulating material layer between the semiconductor chip and the bump structures; and
redistribution patterns within the insulating material layer and connecting the front pads and the bump structures.

14. The semiconductor package of claim 12, wherein the side passivation layer comprises a lower portion contacting the redistribution structure, and
wherein the side passivation layer extends between the second upper portion and the lower portion.

15. A semiconductor package comprising:
a semiconductor chip comprising:
a substrate comprising a front surface and a back surface opposite to the front surface;
front pads on the front surface;
through-electrodes electrically connected to the front pads and penetrating through the substrate and protruding to the back surface; and
back pads on the through-electrodes;
a side passivation layer surrounding the semiconductor chip;
a dielectric layer covering at least a portion of each of the semiconductor chip and the side passivation layer, and surrounding the through-electrodes and the back pads on the back surface of the substrate;
a top semiconductor chip on the dielectric layer, the top semiconductor chip comprising connection pads electrically connected to the back pads; and
bump structures below the semiconductor chip and connected to the front pads,
wherein the side passivation layer comprises an upper surface and a lower surface opposite to the upper surface,
wherein the upper surface of the side passivation layer and the back surface of the substrate extend in a same direction, and
wherein a first distance between the back surface of the substrate and a top surface of the dielectric layer is greater than a second distance between the upper surface of the side passivation layer and the top surface of the dielectric layer.

16. The semiconductor package of claim 15, wherein the semiconductor chip further comprises an insulating layer surrounding the front pads on the front surface of the substrate, and
wherein the lower surface of the side passivation layer is coplanar with a lower surface of the insulating layer, lower surfaces of the front pads, and a lower surface of the dielectric layer.

17. The semiconductor package of claim 15, wherein the dielectric layer comprises:
a gap-fill dielectric layer contacting a side surface of the semiconductor chip and a side surface of each of the through-electrodes; and
a bonding dielectric layer on the gap-fill dielectric layer and contacting a side surface of each of the back pads.

18. The semiconductor package of claim 17, wherein the top semiconductor chip further comprises a bonding insulating layer surrounding the connection pads and contacting the bonding dielectric layer, and
wherein each of the bonding dielectric layer and the bonding insulating layer comprises at least one of silicon oxide (SiO) and silicon carbon nitride (SiCN).

19. A semiconductor package comprising:
a semiconductor chip comprising:
a substrate comprising a front surface and a back surface opposite to the front surface;
front pads on the front surface;
through-electrodes electrically connected to the front pads and penetrating through the substrate and protruding to the back surface; and
back pads disposed on the through-electrodes;
a side passivation layer surrounding the semiconductor chip and spaced from the through-electrodes in a horizontal direction;
a dielectric layer covering at least a portion of each of the semiconductor chip and the side passivation layer, and surrounding the through-electrodes and the back pads on the back surface of the substrate; and
a top semiconductor chip on the semiconductor chip and the dielectric layer, the top semiconductor chip comprising connection pads contacting the back pads.

20. The semiconductor package of claim 19, wherein the side passivation layer extends in a direction intersecting the front surface and the back surface of the semiconductor chip.
